(19) United States
(12) Patent Application Publication
(10) Pub. No.: US 2012/0305055 A1
(43) Pub. Date: Dec. 6, 2012

(54) SOLAR CELL MODULE

(76) Inventors: Taeki WOO, Seoul (KR); Jongkyoung Hong, Seoul (KR); Jemin Yu, Seoul (KR); Taeyoon Kim, Seoul (KR); Eunjoo Lee, Seoul (KR); Seiyoung Mun, Seoul (KR); Youngho Choe, Seoul (KR)

(21) Appl. No.: 13/423,917

(22) Filed: Mar. 19, 2012

(30) Foreign Application Priority Data
May 30, 2011 (KR) 10-2011-0051402

(51) Int. Cl. H01L 31/048

(52) U.S. Cl. 136/251

(57) ABSTRACT

A solar cell module includes a plurality of solar cells, a front substrate positioned at first surfaces of the plurality of solar cells, a front protective member positioned between the front substrate and the plurality of solar cells, a back substrate positioned at second surfaces of the plurality of solar cells, and a back protective member positioned between the back substrate and the plurality of solar cells. A refractive index of the front protective member is greater than a refractive index of the back protective member.

This application claims priority to and the benefit of Korean Patent Application No. 10-2011-0051402, filed in the Korean Intellectual Property Office on May 30, 2011, the entire contents of which are incorporated herein by reference.

### BACKGROUND OF THE INVENTION

1. Field of the Invention

Embodiments of the invention relate to a solar cell module.

2. Description of the Related Art

Solar cells for converting light energy into electric energy using a photoelectric conversion effect have been widely used as means for generating alternative energy and renewable energy.

Because voltage and current produced in the solar cell are very small, a solar cell module of a panel form designed by connecting in parallel or in series several solar cells to one another has been used to obtain a desired amount of voltage and current.

The solar cell module includes a protective member disposed on or under the solar cells, and thus, protects the solar cells from an external environment such as an external impact and moisture.

### SUMMARY OF THE INVENTION

In one aspect, there is a solar cell module including a plurality of solar cells, a front substrate positioned at first surfaces of the plurality of solar cells, a front protective member positioned between the front substrate and the plurality of solar cells, a back substrate positioned at second surfaces of the plurality of solar cells, and a back protective member positioned between the back substrate and the plurality of solar cells, wherein a refractive index of the front protective member is greater than a refractive index of the back protective member.

The refractive index of the front protective member may be about 1.3 to 1.6, and the refractive index of the back protective member may be about 1.2 to 1.5.

The front protective member and the back protective member may be formed of the same material.

The front protective member and the back protective member may be formed of a silicon resin.

The silicon resin may be siloxane, and may be one of polydimethylsiloxane (PDMS) and polydialkylsiloxane (PDAS).

The back protective member may include a fiber network including a plurality of fibers.

A thickness of each of the plurality of fibers may be about 0.01 mm to 1 mm.

Each of the plurality of fibers may be formed of one of a glass fiber, a quartz fiber, a graphite fiber, a nylon fiber, a polyester fiber, an aramid fiber, a polyethylene fiber, a polypropylene fiber, and a silicon carbide fiber.

The front protective member and the back protective member may have the same thickness. Alternatively, a thickness of the back protective member may be greater than a thickness of the front protective member.

An upper part of each of the plurality of solar cells may be covered by the front protective member, and a lower part and sides of each of the plurality of solar cells may be covered by the back protective member.

The upper part of each of the plurality of solar cells may be covered by the front protective member, the lower part of each of the plurality of solar cells may be covered by the back protective member, and the sides of each of the plurality of solar cells may be covered by the front protective member and the back protective member.

The refractive index of the front protective member may be greater than the refractive index of the back protective member by about 10%.

The front protective member and the back protective member may be formed of polydimethylsiloxane (PDMS) having an absorption coefficient of about 1×10⁻²/cm in at least a portion of a wavelength band of 300 nm to 400 nm.

The front protective member and the back protective member may be formed of polydimethylsiloxane (PDMS) having an absorption coefficient of less than 1×10⁻²/cm in a wavelength band of 400 nm to 500 nm.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a cross-sectional view schematically illustrating an example of a solar cell module according to an embodiment of the invention;

FIG. 2 is a graph illustrating absorption coefficients of silicon resin and ethylene vinyl acetate (EVA) depending on a wavelength of light;

FIG. 3 depicts plane views schematically illustrating fiber networks according to embodiments of the invention;

FIG. 4 illustrates a reflective path of light when the light is incident on a front protective member at an angle greater than a critical angle in a solar cell module according to an embodiment of the invention;

FIGS. 5 and 6 are cross-sectional views schematically illustrating other examples of solar cell modules according to embodiments of the invention;

FIG. 7 is a graph illustrating reflectance of light depending on a wavelength of the light according to an embodiment of the invention and according to a comparative example; and

FIGS. 8 and 9 illustrate electric power output from a solar cell module depending on changes in time of day according to an embodiment of the invention and according to a comparative example.

### DETAILED DESCRIPTION OF THE EMBODIMENTS

Embodiments of the invention will be described more fully hereinafter with reference to the accompanying drawings, in which example embodiments of the invention are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

A solar cell module according to an embodiment of the invention is described in detail with reference to the accompanying drawings.

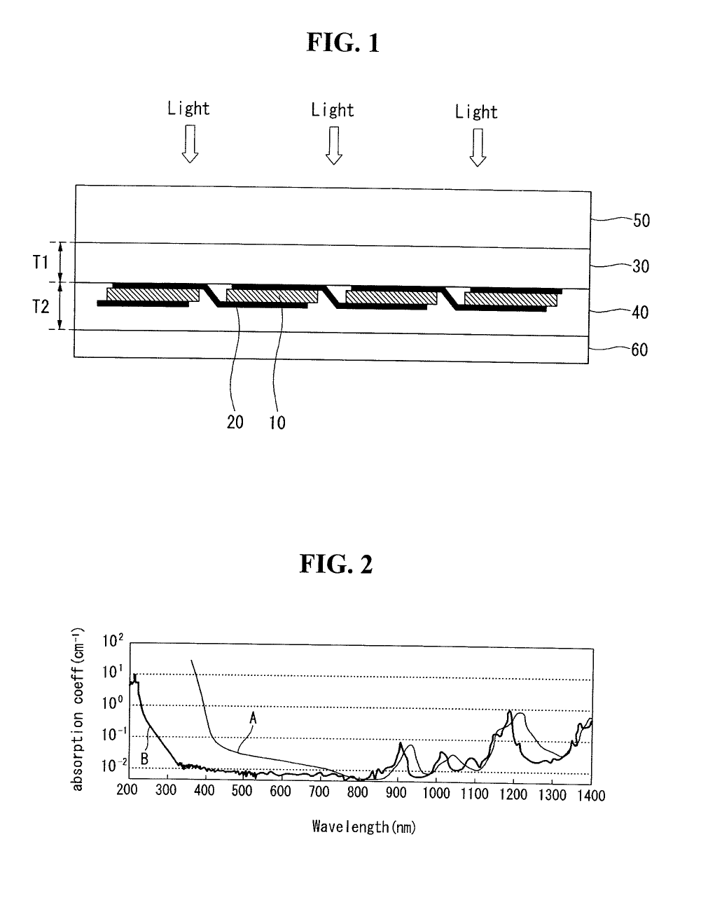

As shown in FIG. 1, a solar cell module according to an embodiment of the invention includes a plurality of solar cells 10, interconnectors 20 for electrically connecting the plurality of solar cells 10 to one another, a front protective member 30 and a back protective member 40 for protecting the plurality of solar cells 10, a front substrate 50 positioned at front surfaces of the plurality of solar cells 10, and a back substrate 60 positioned at back surfaces of the plurality of solar cells 10. In embodiments of the invention, the front substrate 50 may be one having a light transmission property.

The front substrate 50 is positioned at the front surfaces (for example, first surfaces or light receiving surfaces) of the solar cells 10 and is formed, for example, of a tempered glass having a high transmittance. The tempered glass may be a low iron tempered glass containing a small amount of iron. The front substrate 50 may have an embossed inner surface or a textured inner surface, so as to increase a scattering effect of light. The front substrate 50 may have a refractive index of about 1.52.

The front protective member 30 and the back protective member 40 prevent corrosion of metal resulting from penetration of moisture and protect the solar cells 10 and the solar cell module from an impact. The front protective member 30 and the back protective member 40 form an integral body along with the solar cells 10 when a lamination process is performed in a state where the front protective member 30 and the back protective member 40 are respectively disposed on and under the solar cells 10.

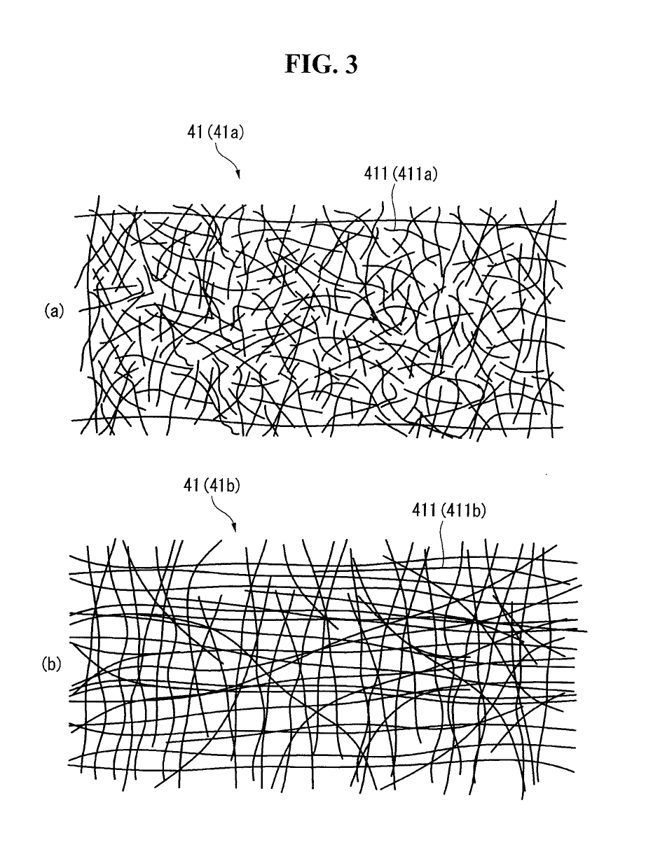

In the embodiment of the invention, the front protective member 30 is formed of silicon resin. The silicon resin may be formed of siloxane such as polydimethylsiloxane (PDMS) and polydialkylsiloxane (PDAS). Absorption coefficients of the silicon resin and ethylene vinyl acetate (EVA) depending on a wavelength of light is described below with reference to FIG. 2.

In FIG. 2, a graph ‘A’ indicates changes in an absorption coefficient of EVA depending on the wavelength of light, and a graph ‘13’ indicates changes in an absorption coefficient of the silicon resin depending on the wavelength of light. In FIG. 2, EVA used in the graph ‘A’ is a product generally used as a protective member of a solar cell, and the silicon resin used in the graph ‘IV according to the embodiment of the invention is PDMS.

As shown in FIG. 2, the absorption coefficient of EVA was greater than the absorption coefficient of PDMS at a short wavelength, for example, at a wavelength of about 300 nm to 700 nm with a marked difference at the wavelength of about 300 nm to 500 nm. Thus, the absorption coefficient of EVA was greater than the absorption coefficient of the silicon resin at the short wavelength band of about 300 nm to 500 nm. For example, at the wavelength range of about 300 nm to 400 nm, the absorption coefficient of the EVA was at least 100 times greater than the absorption coefficient of the PDMS, and at the wavelength of about 500 nm, the absorption coefficient of the EVA was at least two times greater than the absorption coefficient of the PDMS. For example, the front protective member 30 and the back protective member 40 may be formed of the PDMS having an absorption coefficient of about 1×10⁻²/cm in at least a portion of the wavelength band of 300 nm to 400 nm. Additionally, the front protective member 30 and the back protective member 40 may be formed of the PDMS having an absorption coefficient of less than 1×10⁻²/cm in the wavelength band of 400 nm to 500 nm.

The low absorption coefficient of the silicon resin at the short wavelength indicates that light of the short wavelength is sufficiently transmitted. According to the graph shown in FIG. 2, the silicon resin, more specifically, siloxane such as PDMS and PDAS had a transmittance equal to or greater than about 70% at the short wavelength band.

Thus, when the silicon resin is used as the front protective member 30, an amount of light absorbed in the front protective member 30 decreases. Hence, an amount of light incident on the solar cells 10 increases. As a result, output efficiency of the solar cell module is improved. Further, the silicon resin may prevent or reduce the decoloration or discoloration (for example, a reduction in transmittance resulting from a browning or yellowing phenomenon) of the front protective member 30 resulting from an exposure to ultraviolet light and the corrosion of the front protective member 30 resulting from the absorption of air and oxygen. Hence, the durability of the solar cell module is improved.

Because a curing temperature (a temperature equal to or higher than about 80° C., for example, a temperature of about 90° C. to 110° C.) of the silicon resin is lower than a curing temperature (about 165° C.) of EVA, a module forming process of the solar cell module may be performed at a lower temperature. Further, as it takes about 1.5 minutes to cure the silicon resin, while it takes about 16 minutes to cure EVA, thus, time required for the curing processing of the front protective member 30 and the module process may be reduced.

The silicon resin may include of a curing agent of about 50 wt % and may be manufactured as the front protective member 30.

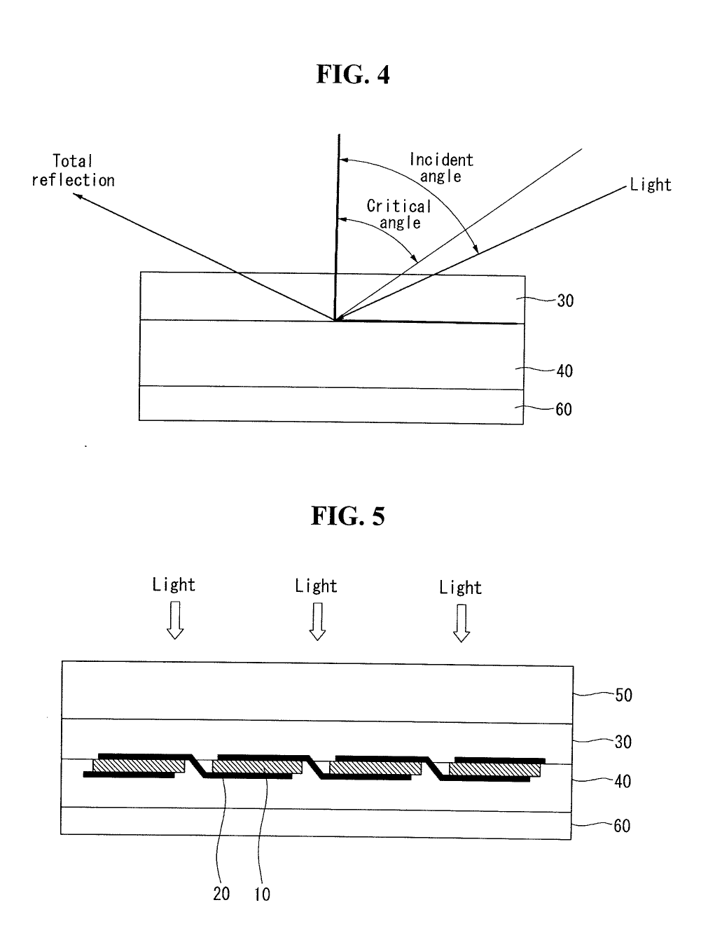

The back protective member 40 is formed of the silicon resin in the same manner as the front protective member 30. The back protective member 40 includes a fiber network 41 including a plurality of fibers 411 which are non-uniformly connected to one another in a mesh form. Examples of the fiber network 41 are shown in (a) and (b) of FIG. 3. A thickness of the fiber network 41 may be less than a thickness of the back protective member 40.

When the back protective member 40 includes the fiber network 41, a space formed in the fiber network 41 is filled with the silicon resin. Thus, when the back protective member 40 includes the fiber network 41, the back protective member 40 is formed of a fiber reinforced silicon resin. Examples of the plurality of fibers 411 include glass fibers, quartz fibers, graphite fibers, nylon fibers, polyester fibers, aramid fibers, polyethylene fibers, polypropylene fibers, and silicon carbide fibers. Other materials may be used. A thickness of each of the fibers 411 may be about 0.01 mm to 1 mm.

A transmittance of the silicon resin forming the back protective member 40 is less than a transmittance of the silicon resin forming the front protective member 30 at the short wavelength. An adhesive strength between the silicon resin forming the back protective member 40 and the back substrate 60 may be about 10 kg/cm² to 15 kg/cm².

Because the transmittance of the back protective member 40 is less than the transmittance of the front protective member 30 at the short wavelength, a portion of light of the short wavelength passing through the front protective member 30 is not transmitted by the back protective member 40. Thus, an amount of light passing through the back protective member 40 is less than an amount of light passing through the front protective member 30. Hence, the back substrate 60, for example, a back sheet may be prevented or reduced from being discolored and degraded.

In the embodiment of the invention, the back protective member 40 may additionally contain a silica-based material so as to increase a sealing effect. As above, when the back protective member 40 includes the fiber network 41, a strength of the back protective member 40 increases. Hence, a bending phenomenon and a crack generation of the back protective member 40 are reduced. As a result, the flatness of the back substrate 60 is improved, and lifetime of the solar cell module increases.

Light, which passes through the plurality of solar cells 10 and reaches the back protective member 40, is reflected by the plurality of fibers 411 included in the back protective member 40 and is again incident on the plurality of solar cells 10. Therefore, the efficiency of the solar cell module is improved.

When the fiber network 41 within the back protective member 40 is disposed closer to the back substrate 60 than the solar cells 10, an amount of light incident on the fiber network 41 increases. Hence, the reflection effect of the fiber network 41 further increases, and the efficiency of the solar cells 10 is improved.

In embodiments of the invention, types of the fiber network 41 and the plurality of fibers 411 includes a fiber network 41a having a plurality of fibers 411a with mostly short fiber strands, which are cross linked in a short range. For example, each of the plurality of fibers 411a intersects with a few others, such as a dozen or so or fewer. Additionally, types of the fiber network 41 and the plurality of fibers 411 includes a fiber network 41b having a plurality of fibers 411b with mostly long fiber strands, which are cross linked in a long range. For example, each of the plurality of fibers 411b intersects with many others, such as a few dozen or more. Accordingly, the number of fibers that each of the fibers 411b intersect may be greater than two times the number of fibers that each of the fibers 411a intersect. Additionally, in other embodiments of the invention, the fiber network 41 may include a combination of the fibers 411a with mostly short fiber and the fibers 411b with mostly long fiber strands, with varying ratio of the fibers 411a and the fibers 411b.

In an alternative example, the back protective member 40 may yet be formed of EVA having a refractive index less than a refractive index of the front protective member 30.

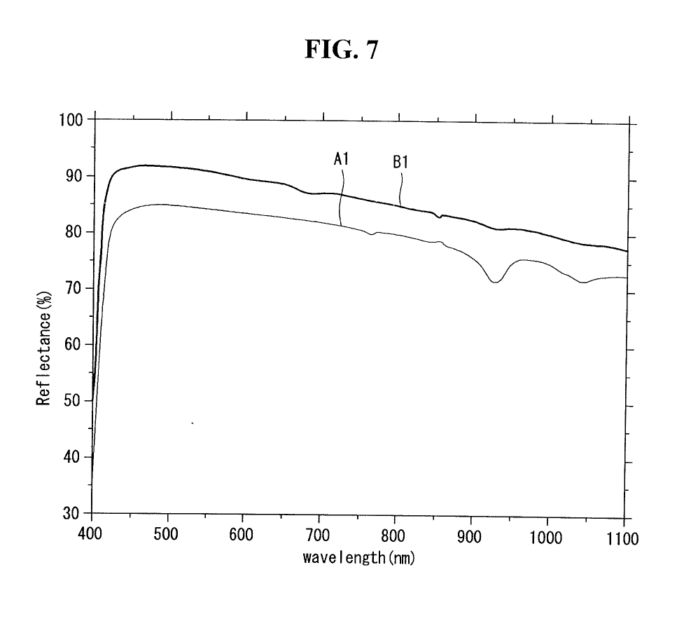

As shown in FIG. 1, the interconnectors 20 connected to the plurality of solar cells 10 contact a lower surface of the front protective member 30 and an upper surface of the back protective member 40. Therefore, an upper surface of each solar cell 10 is covered by the front protective member 30, and a lower surface and sides of each solar cell 10 are covered by the back protective member 40. However, as shown in FIG. 5, at least a portion of the interconnector 20 of each solar cell 10 may be buried in the front protective member 30. Alternatively, as shown in FIG. 6, at least a portion of each solar cell 10 as well as at least a portion of the interconnector 20 of the solar cell 10 may be buried in the front protective member 30.

In this instance, the upper surface of each solar cell 10 contacts the front protective member 30, and thus, is covered by the front protective member 30, and the lower surface of each solar cell 10 contacts the back protective member 40, and thus, is covered by the back protective member 40. However, at least a portion of the side of each solar cell 10 contacts at least one of the front protective member 30 and the back protective member 40.

The sides of each solar cell 10 may contact both the front protective member 30 and the back protective member 40 or may contact only the back protective member 40.

As shown in FIGS. 5 and 6, when at least a portion of each interconnector 20 is buried in the front protective member 30 or at least a portion of each interconnector 20 and at least a portion of each solar cell 10 are buried in the front protective member 30, a location of the solar cells 10 is fixed by the front protective member 30. Hence, mis-arrangement of the solar cells 10 may be prevented or reduced in a subsequent module forming processing operation. In the embodiment of the invention, a maximum thickness T2 of the back protective member 40 is slightly greater than a maximum thickness T1 of the front protective member 30. Alternatively, the maximum thickness T2 of the back protective member 40 may be substantially equal to the maximum thickness T1 of the front protective member 30, if necessary or desired.

In the embodiment of the invention, the maximum thickness T1 of the front protective member 30 and the maximum thickness T2 of the back protective member 40 may be determined within the range of about 0.02 mm to 2 mm. As shown in FIG. 1, when the solar cells 10 are not buried in the front protective member 30 and are positioned on the front protective member 30, the front protective member 30 is positioned between the solar cells 10 and the front substrate 50 which has a substantially uniform thickness irrespective of a location thereof. Therefore, the front protective member 30 has the uniform maximum thickness T1 irrespective of changes in the location. On the other hand, the back protective member 40 has the different thicknesses depending on a location thereof. Namely, a thickness of the back protective member 40 in a formation area of the solar cells 10 is different from a thickness of the back protective member 40 in a non-formation area of the solar cells 10. The maximum thickness T2 of the back protective member 40 is the thickness of the back protective member 40 in the non-formation area of the solar cells 10.

As shown in FIGS. 5 and 6, when at least a portion of each interconnector 20 is buried in the front protective member 30 or at least a portion of each interconnector 20 and at least a portion of each solar cell 10 are buried in the front protective member 30, each of the front protective member 30 and the back protective member 40 has the different thicknesses depending on a formation area of the solar cell 10 attached to the interconnector 20 and a non-formation area of the solar cell 10. Both the maximum thicknesses T1 and T2 of the front protective member 30 and the back protective member 40 are the thicknesses in the non-formation area of the solar cell 10. Thus, each of the front protective member 30 and the back protective member 40 has the different thicknesses depending on a location thereof.

When the thickness of the back protective member 40 positioned at the back surfaces of the solar cells 10 is greater than the thickness of the front protective member 30, the solar cells 10 are more stably protected from an external impact or pollutants, etc. Further, weatherproofing of the solar cell module increases, and thus, the lifespan of the solar cell module increases.

When the maximum thicknesses T1 and T2 of the front protective member 30 and the back protective member 40 are equal to or greater than about 0.02 mm, the solar cells 10 may be more stably sealed. When the maximum thicknesses T1 and T2 of the front protective member 30 and the back protective member 40 are equal to or less than about 2 mm, an amount of light absorbed in the front protective member 30 and the back protective member 40 decreases, and an increase in a thickness of the solar cell module is prevented.

In the embodiment of the invention, the front protective member 30 and the back protective member 40 have the different refractive indexes. For example, the refractive index of the front protective member 30 is greater than the refractive index of the back protective member 40. The refractive indexes of the front protective member 30 and the back protective member 40 and a refractive index of the front substrate 50 may have a difference of about 10%. For example, the refractive index of the front protective member 30 may be about 1.3 to 1.6, the refractive index of the back protective member 40 may be about 1.2 to 1.5, and the refractive index of the front substrate 50 may be about 1.1 to 1.4. For example, the refractive index of the front protective member 30 may be greater than the refractive index of the back protective member 40 by about 10%.

As above, because there is the little difference between the refractive indexes of the front protective member 30 and the back protective member 40 and the refractive index of the front substrate 50, a reflection amount of light incident on the front substrate 50 decreases. When the refractive indexes of the front protective member 30 and the back protective member 40 are equal to or greater than about 1.3 and 1.2, respectively, it may be easier for each of the front protective member 30 and the back protective member 40 to obtain the desired refractive index. When the refractive indexes of the front protective member 30 and the back protective member 40 are equal to or less than about 1.6 and 1.5, respectively, a reflection amount of light may stably decrease.

The refractive indexes of the front protective member 30 and the back protective member 40 may be controlled using K₂O-based material, Na₂O-based material, Li₂O-based material, nonconductive silica-based material, etc. Further, the refractive indexes of the front protective member 30 and the back protective member 40 may be controlled by changing densities of the front protective member 30 and the back protective member 40 by varying a pressure, a process temperature, etc., that is applied to the front protective member 30 and the back protective member 40 during a processing operation, for example that is performed in a process room.

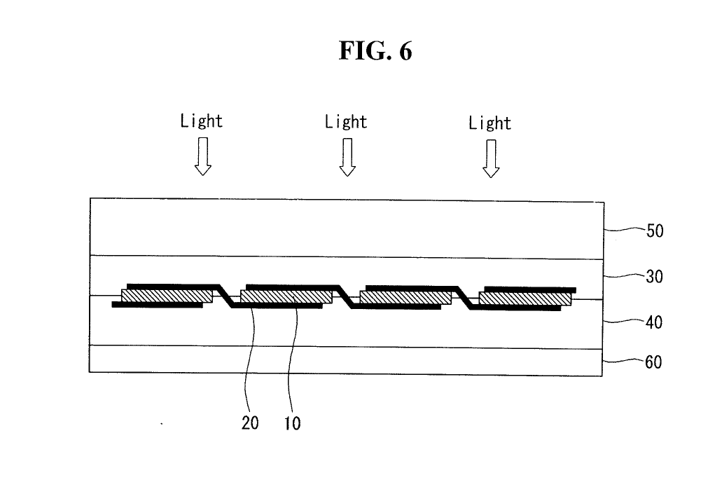

As above, because the refractive index of the front protective member 30 is different from (for example, is greater than) the refractive index of the back protective member 40, when light from the outside is incident on the back protective member 40 at an incident angle (for example, at sunrise or at sunset) greater than a critical angle of the front protective member 30 and the back protective member 40 through the front protective member 30 as shown in FIG. 4, the incident light is totally reflected by the back protective member 40 and then is again incident on the plurality of solar cells 10.

On the other hand, in a comparative example where the front protective member 30 and the back protective member 40 are formed of a material, for example, EVA having the same refractive index, light incident on the back protective member 40 through the front protective member 30 is partially reflected by the back substrate 60 and then is again incident on the plurality of solar cells 10. However, a portion of the light is absorbed in the back protective member 40.

Accordingly, an amount of light again incident on the solar cells 10 according to the embodiment of the invention, in which the refractive index of the front protective member 30 is greater than the refractive index of the back protective member 40, is more than an amount of light again incident on the solar cells 10 in the comparative example.

In the embodiment of the invention, because a re-incident operation of light is additionally performed by the back substrate 60, an amount of light again incident on the solar cells 10 further increases compared to the comparative example. Hence, the efficiency of each solar cell 10 is improved, and the efficiency of the solar cell module is improved. Further, because an amount of light incident on the back protective member 40 decreases, the discoloration and the degradation of the back protective member 40 are prevented or reduced. Hence, the efficiency of the solar cell module is further improved.

The back substrate 60 is manufactured as a thin sheet formed of an insulating material, for example, fluoropolymer/polyeaster/fluoropolymer (FP/PE/FP). Insulating sheets formed of other insulating materials may be used for the back substrate 60.

The back substrate 60 prevents moisture or oxygen from penetrating into a back surface of the solar cell module, thereby protecting the solar cells 10 from an external environment. The back substrate 60 may have a multi-layered structure including a moisture/oxygen penetrating prevention layer, a chemical corrosion prevention layer, a layer having insulating characteristics, etc.

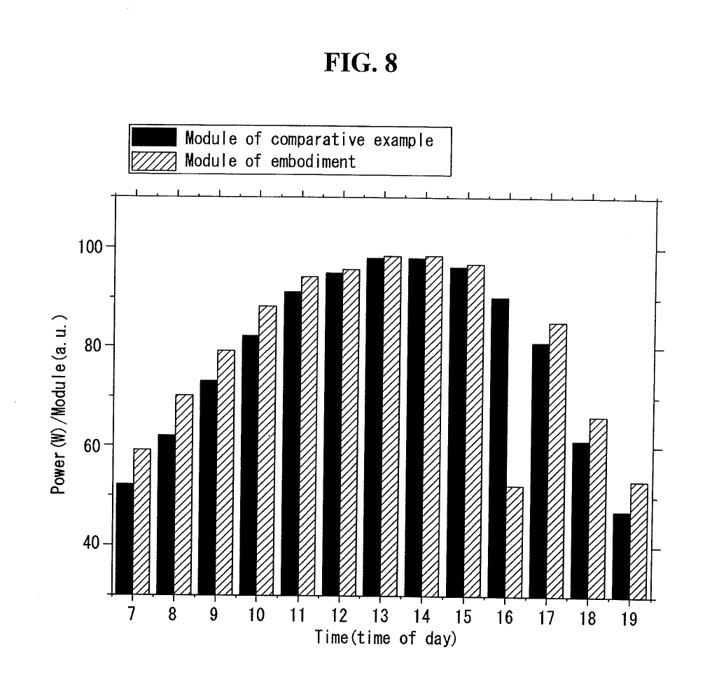

A reflectance of light depending on a wavelength of the light and electric power output from the solar cell module depending on changes in time in the embodiment of the invention and the comparative example are described with reference to FIGS. 7 to 9.

FIG. 7 illustrates a reflectance of light reflected from the back surface of the solar cell module when the front protective member had the refractive index of about 1.48 and the back protective member had the refractive index of about 1.37 in the embodiment of the invention, and both the front protective member and the back protective member had the refractive index of about 1.48 in the comparative example. In FIG. 7, an incident angle of the light was about 70 °.

In FIG. 7, a graph A1 according to the comparative example indicates a reflectance of light generated between the back protective member and the back substrate, which have a refractive index difference, because the front protective member and the back protective member have the same refractive index. A graph B1 according to the embodiment of the invention indicates a reflectance of light generated between the front protective member and the back protective member having a refractive index difference and between the back protective member and the back substrate having a refractive index difference.

As shown in FIG. 7, unlike the comparative example, in the embodiment of the invention, because the reflection of light between the front protective member and the back protective member was additionally generated throughout the measured wavelength of light, the reflectance of light reflected on the solar cell in the graph B1 according to the embodiment of the invention was greater than that in the graph A1 according to the comparative example throughout the measured wavelength of light.

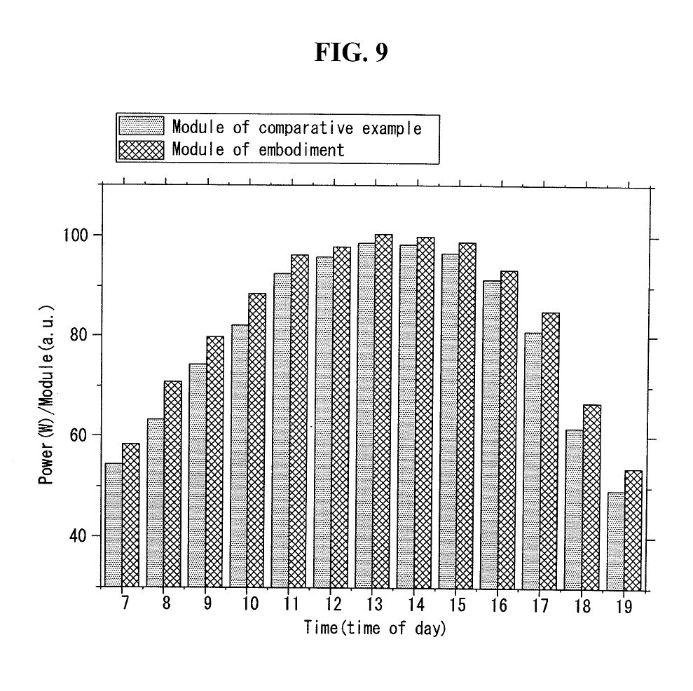

FIGS. 8 and 9 illustrate electric power output from the solar cell module depending on changes in time of day according to the embodiment of the invention and according to the comparative example after the solar cell module is completed by installing the front substrate on the front protective member. In FIGS. 8 and 9, the front protective member had the refractive index of about 1.53 and the back protective member had the refractive index of about 1.37 in the embodiment of the invention, and both the front protective member and the back protective member had the refractive index of about 1.48 in the comparative example. Experimental values illustrated in FIGS. 8 and 9 was measured at the latitude of 36.1° in winter, and the solar cells of the solar cell module used in FIGS. 8 and 9 was manufactured using single crystal silicon.

In FIG. 8, the surface of the front substrate has a flat surface, on which the embossing process or the texturing process is not performed. In FIG. 9, the surface of the front substrate has the embossed surface or the textured surface, on which the embossing process or the texturing process is performed, so as to reduce the reflectance of light.

As shown in FIGS. 8 and 9, the electric power output from the solar cell module according to the embodiment of the invention was greater than the electric power output from the solar cell module according to the comparative example depending on changes in time of day. As described above, in the embodiment of the invention, because an amount of light reflected on the solar cells increases due to the refractive index difference between the front protective member and the back protective member, the electric power output from the solar cell module according to the embodiment of the invention further increased compared to the comparative example. In FIGS. 8 and 9, the measured electric power is arbitrary unit (a.u.).

The solar cell module having the above-described configuration may be manufactured through the following method. First, silicon resin for the front protective member is coated on one surface of the front substrate 50 and is left for a predetermined time (for example, about 30 to 60 seconds) to level the silicon resin. In this instance, a frame of a predetermined height capable of surrounding the front substrate 50 may be installed and may prevent the coated silicon resin from overflowing outside the front substrate 50.

Subsequently, the front substrate 50, on which the liquid silicon resin is coated, is disposed in an oven and is heated at a temperature equal to or higher than about 80° C., for example, at about 90° C. to 110° C. and then the liquid silicon resin is cured to form the front protective member 30. Hence, the front protective member 30 is formed using the silicon resin. When curing processing is performed, the front protective member 30 is attached to the front substrate 50, and one surface of the front protective member 30, i.e., the surface opposite the surface of the front protective member 30 attached to the front substrate 50 is an uneven surface.

Next, the plurality of solar cells 10 are disposed on the front protective member 30. Silicon resin for the back protective member 40 is coated to a thickness of about 3 mm to 5 mm and is left for about 30 to 60 seconds to level the silicon resin.

In this instance, a process for coating the liquid silicon resin for the back protective member 40 may be performed using a frame in the same manner as the silicon resin for the front protective member 30.

In the process for coating and leveling the silicon resin for the back protective member 40, the liquid silicon resin for the back protective member 40 is filled in a space between the adjacent solar cells 10 and a space between the solar cells 10 and the front protective member 30.

After the process for leveling the silicon resin for the back protective member 40 is completed, the fiber network 41 is disposed on the silicon resin and the back substrate 60 is disposed on the fiber network 41.

When fiber network 41 and the back substrate 60 are disposed on the liquid silicon resin for the back protective member 40, the silicon resin is pressed because of the weight of the fiber network 41 and the back substrate 60. Hence, the silicon resin is filled in a space between the fibers 411 of the fiber network 41. The silicon resin filled in the space between the fibers 411 contacts the back substrate 60.

When at least a portion of the fiber network 41 does not contact the back substrate 60, the silicon resin for the back protective member 40 is filled in a space between the fiber network 41 and the back substrate 60.

A predetermined pressure may be firstly applied to an upper part of the back substrate 60, so that the silicon resin for the back protective member 40 can be sufficiently filled in the space between the fibers 411 and/or the space between the fiber network 41 and the back substrate 60.

In an alternative example, the fiber network 41 may not be positioned on the silicon resin for the back protective member 40.

Afterwards, a process for curing the silicon resin for the back protective member 40 is performed to form the back protective member 40 attached to the back substrate 60. Hence, the solar cell module is completed. The curing process of the silicon resin for the back protective member 40 may be performed by heating the silicon resin for the back protective member 40 in the oven at a temperature equal to or higher than about 80° C., for example, at about 90° C. to 110° C., in the same manner as the silicon resin for the front protective member 30. Alternatively, the curing process of the silicon resin for the back protective member 40 may be performed using a general laminating device. When the silicon resin for the back protective member 40 is cured, the silicon resin for the back protective member filled in the space of the fiber network 41 is attached to the back substrate 60. Further, the silicon resin for the back protective member filled in the space between the fiber network 41 and the back substrate 60 is attached to the back substrate 60.

The fiber network 41 of the back protective member 40 may be substantially separated from the back substrate 60 by a predetermined distance. The substantial separation between the fiber network 41 and the back substrate 60 may include that most (except a portion) of the surface of the fiber network 41 opposite the back substrate 60 is separated from the back substrate 60. Thus, the fiber network 41 may be positioned inside the silicon resin for the back protective member 40 at a location closer to the back substrate 60 than the solar cells 10.

In another method, the back protective member 40 may be formed by performing a first coating process of the silicon resin for the back protective member 40 to dispose the fiber network 41 and then performing a second coating process of the silicon resin for the back protective member 40.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module comprising:
a plurality of solar cells;
a front substrate positioned at first surfaces of the plurality of solar cells;
a front protective member positioned between the front substrate and the plurality of solar cells;
a back substrate positioned at second surfaces of the plurality of solar cells; and
a back protective member positioned between the back substrate and the plurality of solar cells,
wherein a refractive index of the front protective member is greater than a refractive index of the back protective member.

2. The solar cell module of claim 1, wherein the refractive index of the front protective member is about 1.3 to 1.6, and the refractive index of the back protective member is about 1.2 to 1.5.

3. The solar cell module of claim 1, wherein the front protective member and the back protective member are formed of the same material.

4. The solar cell module of claim 3, wherein the front protective member and the back protective member are formed of silicon resin.

5. The solar cell module of claim 4, wherein the silicon resin is siloxane, and is one of polydimethylsiloxane (PDMS) and polydialkylsiloxane (PDAS).

6. The solar cell module of claim 1, wherein the back protective member includes a fiber network including a plurality of fibers.

7. The solar cell module of claim 6, wherein a thickness of each of the plurality of fibers is about 0.01 mm to 1 mm.

8. The solar cell module of claim 6, wherein each of the plurality of fibers is formed of one of a glass fiber, a quartz fiber, a graphite fiber, a nylon fiber, a polyester fiber, an aramid fiber, a polyethylene fiber, a polypropylene fiber, and a silicon carbide fiber.

9. The solar cell module of claim 1, wherein the front protective member and the back protective member have the same thickness.

10. The solar cell module of claim 1, wherein a thickness of the back protective member is greater than a thickness of the front protective member.

11. The solar cell module of claim 1, wherein an upper part of each of the plurality of solar cells is covered by the front protective member, and a lower part and sides of each of the plurality of solar cells are covered by the back protective member.

12. The solar cell module of claim 1, wherein an upper part of each of the plurality of solar cells is covered by the front protective member, a lower part of each of the plurality of solar cells is covered by the back protective member, and sides of each of the plurality of solar cells are covered by the front protective member and the back protective member.

13. The solar cell module of claim 1, wherein the refractive index of the front protective member is greater than the refractive index of the back protective member by about 10%.

14. The solar cell module of claim 1, wherein the front protective member and the back protective member are formed of polydimethylsiloxane (PDMS) having an absorption coefficient of about 1×10⁻²/cm in at least a portion of a wavelength band of 300 nm to 400 nm.

15. The solar cell module of claim 1, wherein the front protective member and the back protective member are formed of polydimethylsiloxane (PDMS) having an absorption coefficient of less than 1×10⁻²/cm in a wavelength band of 400 nm to 500 nm.
